(19) United States
(12) Patent Application Publication
(10) Pub. No.: US 2025/0022857 A1
(43) Pub. Date: Jan. 16, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Kyoung Yeon Lee, Incheon (KR); Byong Jin Kim, Seoul (KR); Ji Yeon Ryu, Incheon (KR)

(73) Assignee: Amkor Technology Singapore Holding Pte. Ltd., Singapore (SG)

(21) Appl. No.: 18/349,719

(22) Filed: Jul. 10, 2023

(51) Int. Cl. H01L 25/16; H01L 21/48; H01L 23/00; H01L 23/498; H01Q 1/22

(52) U.S. Cl. CPC H01L 25/16; H01L 21/4857; H01L 23/49822; H01L 24/24; H01L 24/32; H01Q 1/2283; H01L 23/3128; H01L 24/16; H01L 24/73; H01L 2224/16227; H01L 2224/24227; H01L 2224/32225; H01L 2224/73204; H01L 2924/19106

(57) ABSTRACT

In one example, an electronic device can include a first redistribution structure. A first electronic component can be disposed on a first side of the first redistribution structure. A first passive component can be on a second side of the first redistribution structure with the first redistribution structure between the first passive component and the first electronic component. A first internal interconnect can be adjacent a lateral side of the first redistribution structure and coupled to the first redistribution structure. A second internal interconnect can be adjacent a lateral side of the first passive component and coupled to the first redistribution structure. An antenna substrate can be disposed over a first side of the first electronic component. A second redistribution structure can be disposed over a second side of the first electronic component. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2J show an example method for manufacturing an electronic device.

FIG. 3 shows a cross-sectional view of an example electronic device.

FIG. 4 shows a cross-sectional view of an example electronic device.

FIGS. 5A to 5J show an example method for manufacturing an electronic device.

FIG. 6 shows a cross-sectional view of an example electronic device.

The following discussion provides various examples of electronic devices and methods of manufacturing electronic devices. Such examples are non-limiting, and the scope of the appended claims should not be limited to the particular examples disclosed. The detailed description herein is presented for purposes of illustration only and not of limitation. For example, the steps recited in any of the method or process descriptions may be executed in any order and are not necessarily limited to the order presented. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements.

### DESCRIPTION

An example electronic device includes a first redistribution structure. A first electronic component can be disposed on a first side of the first redistribution structure. A first passive component can be on a second side of the first redistribution structure with the first redistribution structure between the first passive component and the first electronic component. A first internal interconnect can be adjacent a lateral side of the first redistribution structure and coupled to the first redistribution structure. A second internal interconnect can be adjacent a lateral side of the first passive component and coupled to the first redistribution structure. An antenna substrate can be disposed over a first side of the first electronic component. A second redistribution structure can be disposed over a second side of the first electronic component.

In various examples, the electronic device can include a second passive component disposed between the first redistribution structure and the first electronic component. The first redistribution structure can be between the second passive component and the first electronic component. The antenna substrate can be between the second passive component and the first passive component. The first passive component can be between the first redistribution structure and the second redistribution structure. The first electronic component can be between the first redistribution structure and the second redistribution structure. The electronic device can include a die attach material coupling the first electronic component to the antenna substrate. The electronic device can include an active side of the first electronic component coupled to the second redistribution structure. The electronic device can include an active side of the first electronic component coupled to the first redistribution structure. The first internal interconnect can be between the first electronic component and the second electronic component. The electronic device can include a first encapsulant disposed around the first internal interconnect, the first electronic component, and the second electronic component. The first redistribution structure can be between the first encapsulant and the second encapsulant. The second redistribution structure can be between the second electronic component and the first electronic component.

An example method of making an electronic device includes the steps of providing a first substrate, providing a first internal interconnect over the first substrate, and providing a first passive component over the first substrate and adjacent a lateral side of the first internal interconnect. A second substrate can be provided over the first passive component and the first internal interconnect. The second substrate can include a redistribution structure. An electronic component can be provided over the second substrate. A second internal interconnect can be provided adjacent a lateral side of the electronic component. A third substrate can be provided over the electronic component and the second internal interconnect. The third substrate can include an antenna.

Various example methods can include the step of providing a second passive component over the second substrate and adjacent the electronic component. The method can include providing a first encapsulant over the first substrate and around the first passive component and the first internal interconnect. A second encapsulant can be provided over the second substrate and around the electronic component and the second internal interconnect. Providing the third substrate further can include patterning a conductive layer to form the antenna. A second passive component can be provided over the first substrate and adjacent the first passive component. The example method can include providing a second passive component over an outer side of the third substrate.

Other examples are included in the present disclosure. Such examples may be found in the figures, in the claims, or in the description of the present disclosure.

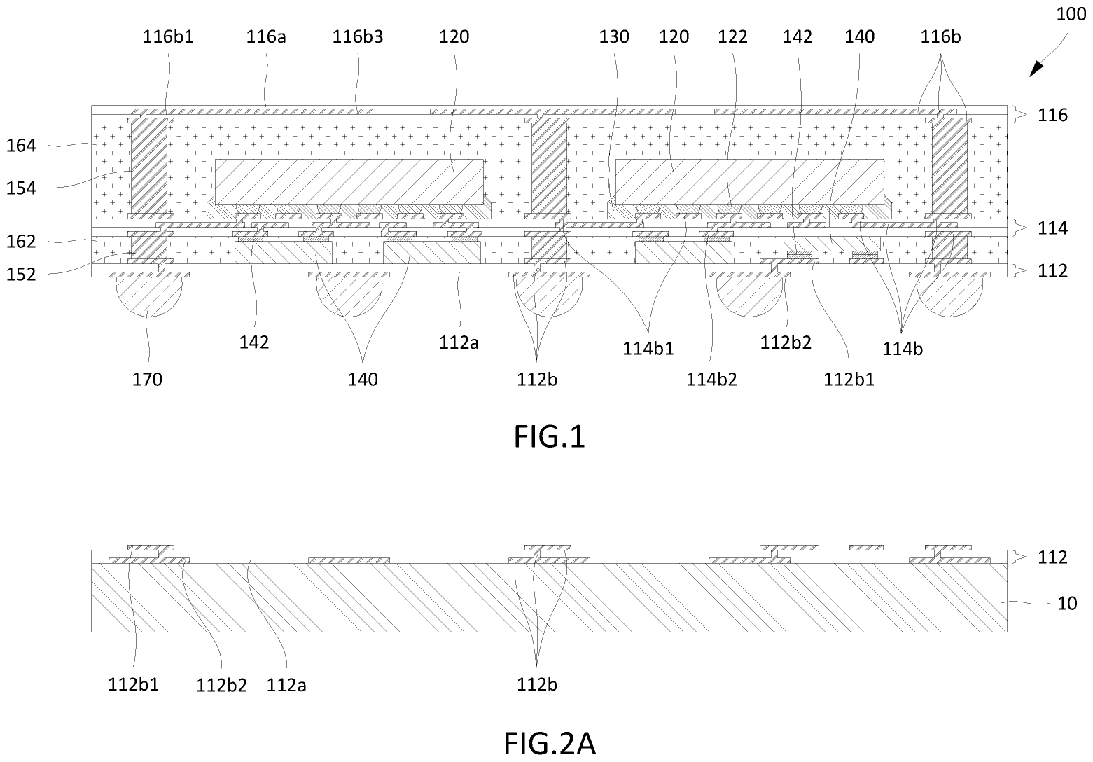

FIG. 1 shows a cross-sectional view of an example electronic device 100. In the example shown in FIG. 1, electronic device 100 can comprise substrates 112, 114, and 116, electronic component 120, underfill 130, passive components 140, internal interconnects 152 and 154, encapsulants 162 and 164, and external interconnects 170.

Some examples of substrates 112, 114, and 116 can comprise substrate 112, substrate 114, and substrate 116. Substrate 112 can comprise dielectric structure 112a and conductive structures 112b. Conductive structures 112b can comprise substrate inward terminals 112b1 and substrate outward terminals 112b2. Substrate 114 can comprise dielectric structures 114a and conductive structures 114b. Conductive structures 114b can comprise substrate inward terminals 114b1 and substrate outward terminals 114b2. Substrate 116 can comprise dielectric structures 116a and conductive structures 116b. Conductive structures 116b can comprise substrate inward terminals 116b1 and antenna pattern 116b3.

Some examples of electronic component 120 can comprise component interconnects 122. Passive components 140 can comprise passive component interconnects 142. Internal interconnects 152 and 154 can comprise internal interconnects 152 and internal interconnects 154. Encapsulants 162 and 164 can comprise encapsulant 162 and encapsulant 164.

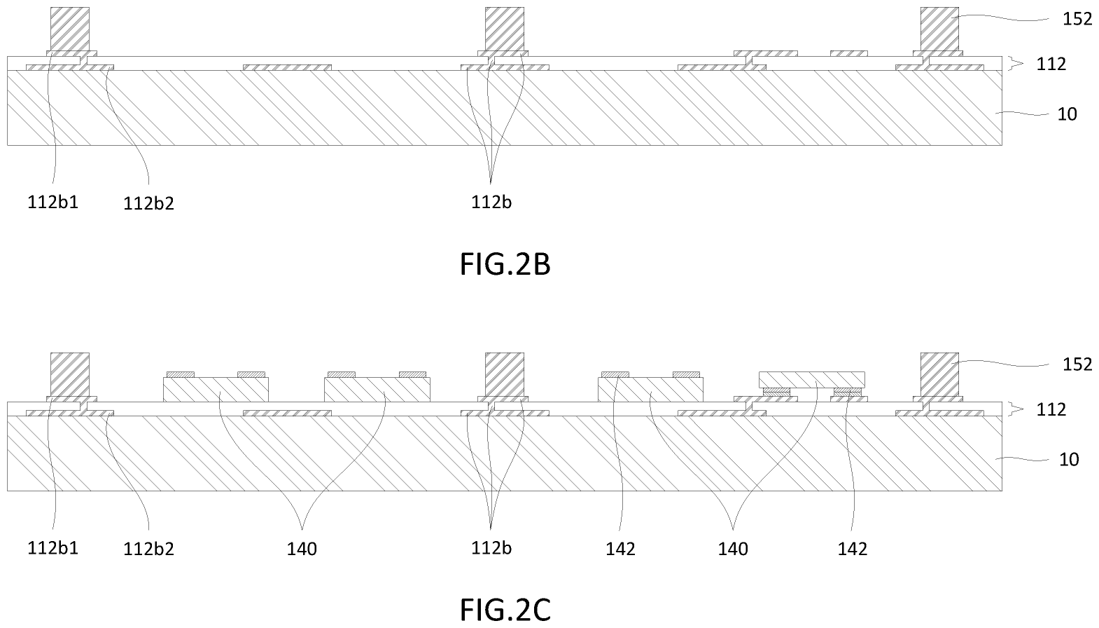

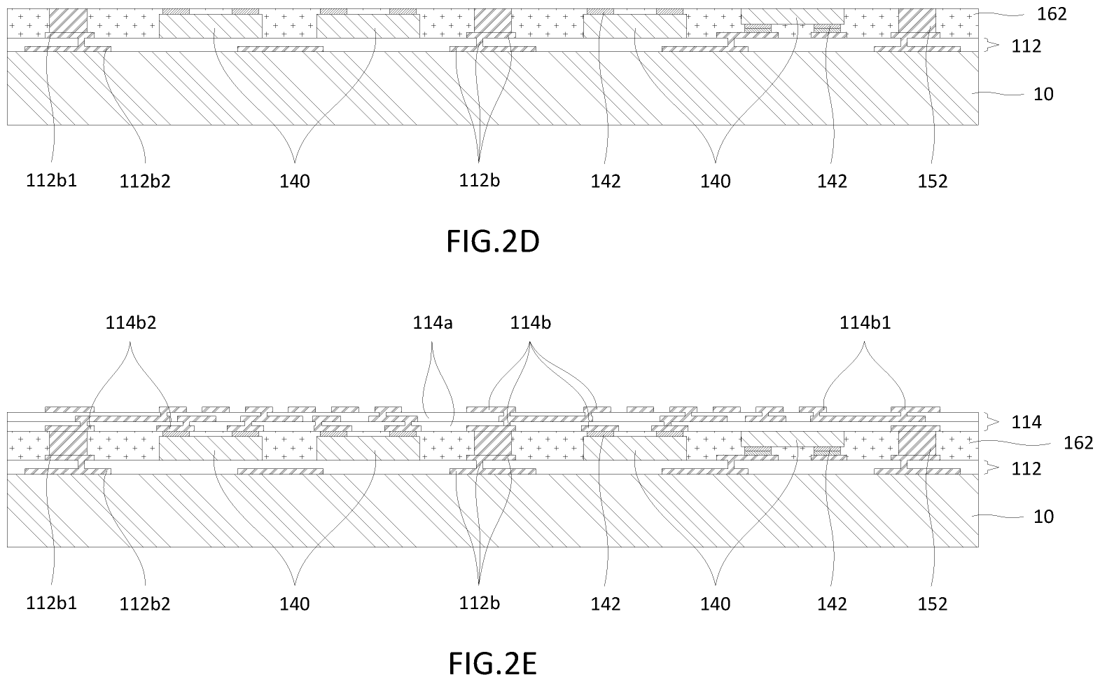

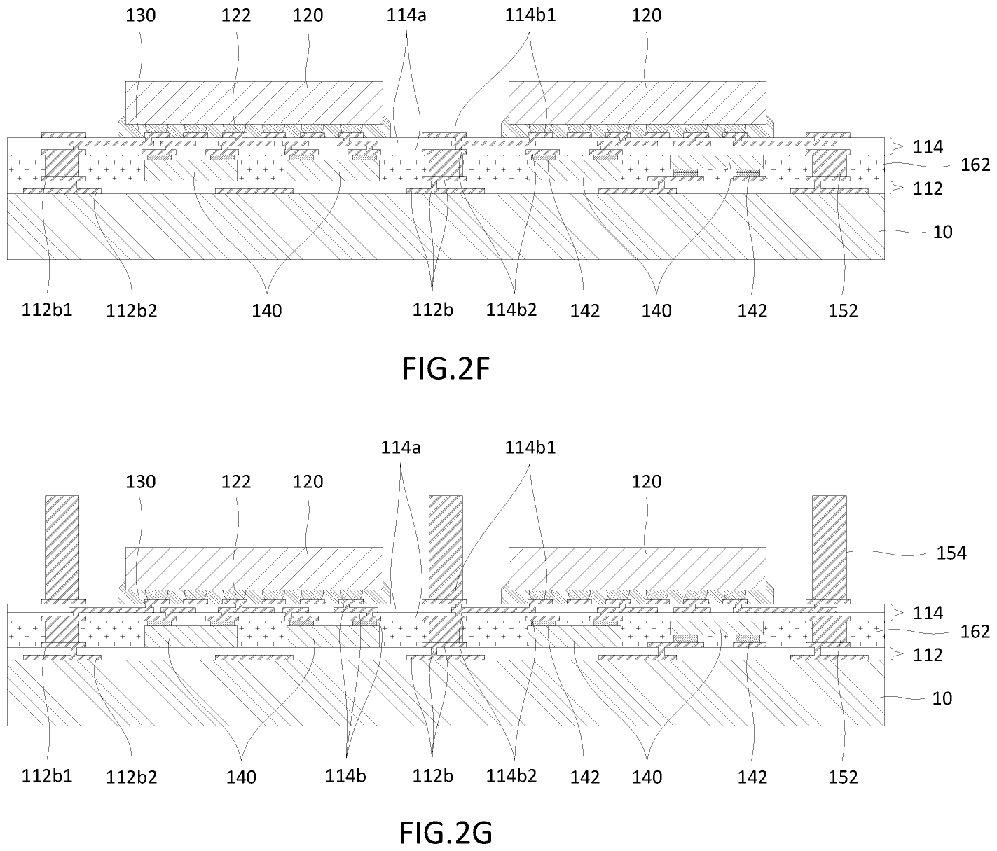

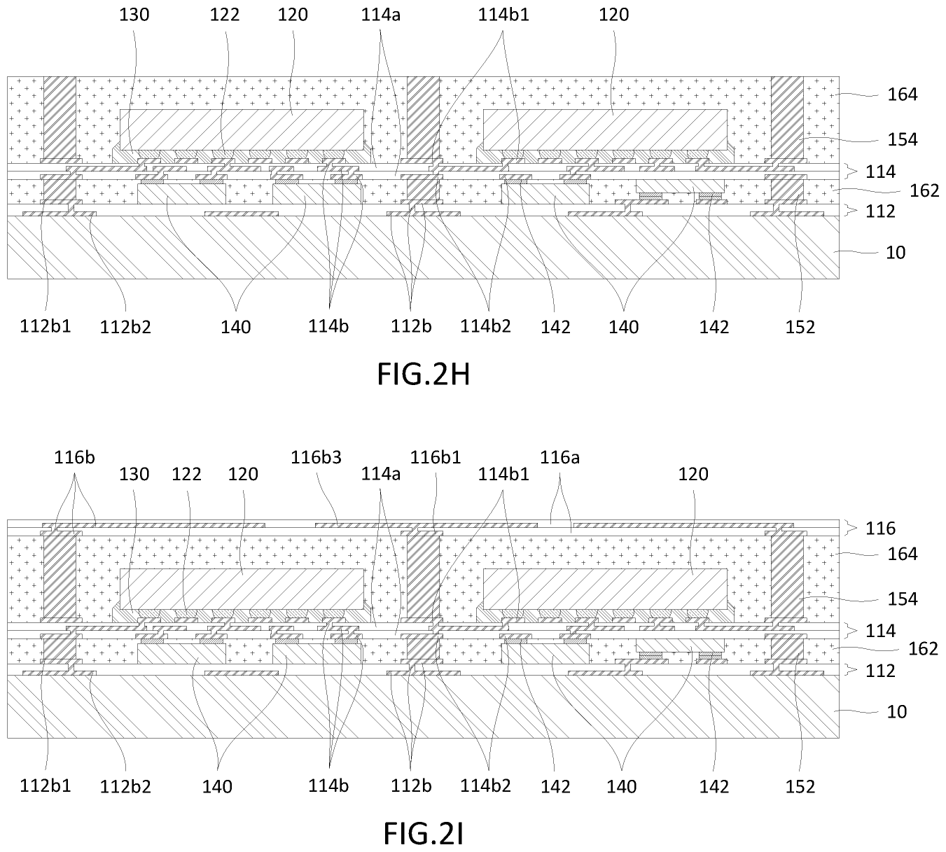

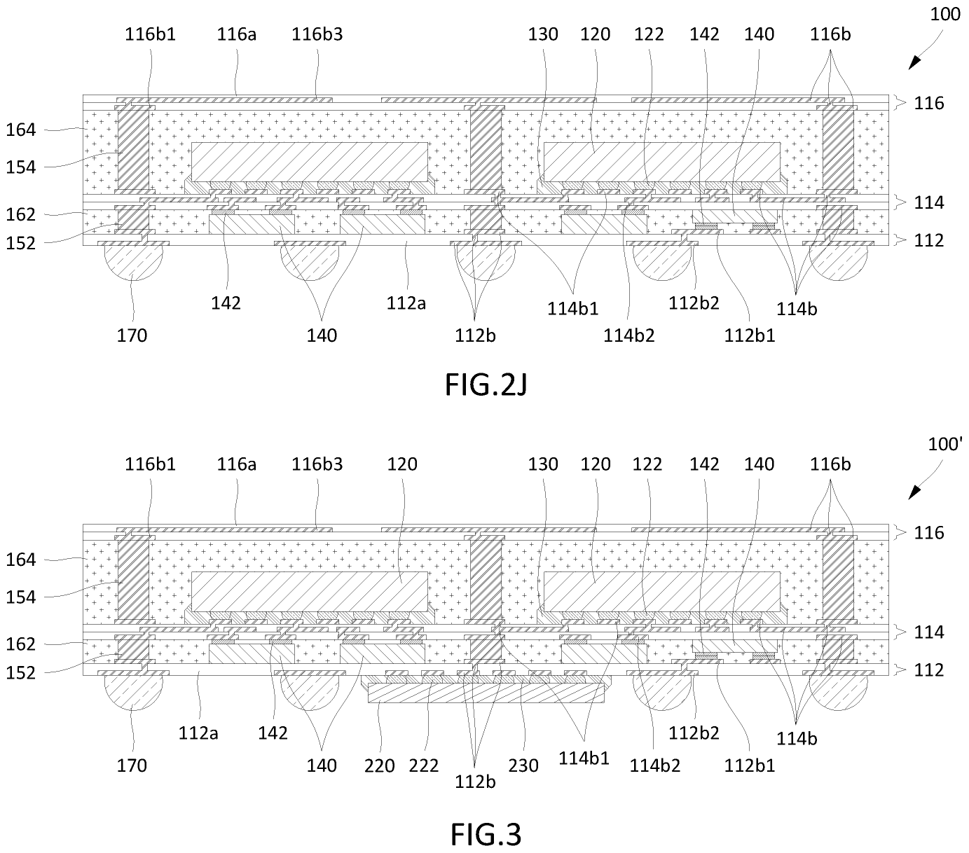

FIGS. 2A to 2J illustrate an example method for manufacturing an electronic device. FIG. 2A shows a cross section view of electronic device 100 at an early stage of manufacture. In the example shown in FIG. 2A, substrate 112 can be provided on the surface of carrier 10. Substrate 112 can comprise dielectric structure 112a and conductive structures 112b. Conductive structures 112b can comprise substrate inward terminal 112b1 and substrate outward terminal 112b2.

In some examples, substrate outward terminals 112b2 can be provided on the surface of carrier 10. Substrate outward terminals 112b2 can have patterns on the surface of carrier 10. Substrate outward terminals 112b2 can comprise or be referred to as conductors, conductive materials, pads, lands, or under-bump-metallurgies (UBMs). In some examples, substrate outward terminals 112b2 can comprise copper, gold, silver, or nickel. In some examples, substrate outward terminals 112b2 can be provided through plating. For example, substrate outward terminals 112b2 can be provided through plating to have a pattern by using a seed layer as a seed after a metal seed layer is provided to cover the upper surface of carrier 10, and a mask pattern is provided to cover the upper surface of the seed layer. For example, the mask pattern can comprise a photoresist material. The mask pattern can be removed after substrate outward terminals 112b2 are formed. In some examples, the thicknesses of substrate outward terminals 112b2 can range from approximately 3 to 20 μm (micrometers).

In some examples, carrier 10 can be a substantially planar plate. Carrier 10 can comprise or be referred to as a plate, a board, a wafer, a panel, or a strip. For example, carrier 10 can be made of steel, stainless steel, aluminum, copper, ceramic, glass, or a wafer. In some examples, the thickness of carrier 10 can range from approximately 300 to 2000 μm, and the width of carrier 10 can range from approximately 100 to 300 millimeters (mm). Carrier 10 serves to enable integral handling of components during a process of providing substrates 112, 114, and 116, electronic components 120, underfill 130, passive components 140, internal interconnects 152 and 154, and encapsulants 162 and 164.

In some examples, carrier 10 can comprise a temporary bond layer provided on the surface. Substrate outward terminals 112b2 can be provided on the surface of the temporary bond layer of carrier 10. The temporary bond layer can be formed by performing, on the surface of carrier 10, a coating process such as spin coating, doctor blade coating, casting, painting, spray coating, slot die coating, curtain coating, slide coating, or knife over edge coating, a printing process such as screen printing, pad printing, gravure printing, flexography printing, or offset printing, an inkjet printing process, an intermediate technology between coating and printing, or by direct attachment of an adhesive film or an adhesive tape. In some examples, the temporary bond layer can comprise or be referred to as a temporary adhesive film, a temporary adhesive tape, or a temporary adhesive coating. For example, the temporary bond layer can be a heat release tape (film) or an optical release tape (film), and the adhesive strength can be weakened or removed by heat or light. In some examples, the temporary bond layer can have the adhesive strength weakened or removed by physical or chemical external force. The temporary bond layer can allow carrier 10 to be separated from substrate 112 before external interconnects 170 to be described below are provided.

In some examples, dielectric structure 112a can be provided on the upper sides of substrate outward terminals 112b2 and carrier 10. After dielectric structure 112a is provided to cover the substrate outward terminals 112b2 and carrier 10, openings exposing substrate outward terminals 112b2 can be provided. For example, the openings can be formed by forming a mask pattern on the upper side of the dielectric structure 112a and then removing the exposed dielectric structure 112a through etching. In some examples, the openings can be referred to as or comprise apertures or holes. In some examples, dielectric structure 112a can comprise or be referred to as a dielectric layer, a coreless layer, or a filler-free layer. For example, dielectric structure 112a can comprise an electrical insulating material such as polyimide (PI), benzocyclobutene (BCB), polybenzoxazole (PBO), resin or Ajinomoto buildup film (ABF). In some examples, dielectric structure 112a can be formed by spin coating, spray coating, dip coating, or rod coating. In some examples, the thickness of dielectric structure 112a can range from approximately 5 to 30 μm.

In some examples, conductive structures 112b can be provided to cover the upper side of dielectric structure 112a and substrate outward terminals 112b2. Conductive structures 112b can be provided to have multiple patterns, and the respective patterns can be electrically connected to conductive structures 112b. In some examples, conductive structures 112b can comprise or be referred to as conductive layers, traces, pads, TVS, TGS, vias, redistribution layers (RDLs), wiring patterns, or circuit patterns. In some examples, conductive structures 112b can comprise copper, gold, silver, or nickel. In some examples, conductive structures 112b can include corresponding elements, features, materials, or manufacturing methods similar to or the same as those previously described for substrate outward terminals 112b2. Substrate outward terminals 112b2 can be parts of conductive structures 112b. In some examples, the overall thickness of conductive structures 112b can range from approximately 3 to 20 μm. Conductive structures 112b can be positioned on the upper sides of dielectric structure 112a and can comprise or be referred to as substrate inward terminals 112b1.

Although completed substrate 112 has been described as including one dielectric structure 112a and two layers of conductive structures 112b in the example of FIG. 2A, the number of layers in substrate 112 can be less or more than two. One or more layers or elements of conductive structures 112b can be interleaved with dielectric structure 112a. Substrate inward terminals 112b1 and substrate outward terminals 112b2 can be spaced apart from each other in a row or column direction on opposing sides of substrate 112. In some examples, the overall thickness of substrate 112 can range from approximately 5 to 30 μm.

In some examples, substrate 112 can be a redistribution layer (“RDL”) substrate or redistribution structure. RDL substrates can comprise one or more conductive redistribution layers and one or more dielectric layers. RDL substrates can be formed layer by layer over an electronic device to where the RDL substrate is to be coupled. RDL substrates can be formed layer by layer over a carrier and can be entirely or partially removed after an electronic device is coupled to the RDL substrate. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and can define respective conductive redistribution patterns or traces configured to collectively fan-out electrical traces outside the footprint of the electronic device, or to fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), and/or SiON. The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4, and these types of RDL substrates can comprise or be referred to as coreless substrates. Other substrates in this disclosure can also comprise an RDL substrate.

In some examples, substrate 112 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, or other inorganic particles for rigidity or structural support. Since the dielectric layers are non-photo-definable, features, such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process. Other substrates in this disclosure can also comprise a pre-formed substrate.

FIG. 2B shows a cross section view of electronic device 100 at a later stage of manufacture. In the example shown in FIG. 2B, internal interconnects 152 can be provided over substrate 112. Internal interconnects 152 can be coupled to substrate inward terminals 112b1. Internal interconnects 152 can be provided by electrolytic plating, electroless plating, sputtering, PVD, CVD, MOCVD, ALD, LPCVD, or PECVD. In some examples, internal interconnects 152 can be made of copper, gold, silver, palladium, or nickel. Internal interconnects 152 can comprise posts, pillars, vertical wires, bumps, or solder-coated-metallic-core-balls. In some examples, the heights of internal interconnects 152 can range from approximately 3 to 200 μm. Internal interconnects 152 can be spaced apart from each other in a row or column direction.

FIG. 2C shows a cross section view of electronic device 100 at a later stage of manufacture. In the example shown in FIG. 2C, passive components 140 can be provided over substrate 112. In some examples, passive components 140 can comprise passive component interconnects 142 provided on the upper or lower side. Passive component interconnects 142 be located on a side of passive component 140 oriented towards or away from substrate 112. Passive components 140 can include capacitors, inductors, or resistors, for example. In some examples, passive components 140 can comprise passive component interconnects 142 provided on the upper or lower side.

In some examples, passive components 140 can comprise passive component interconnects 142 provided on the lower side. Passive component interconnects 142 can be provided on the lower sides of passive components 140 to be spaced apart from each other in a row or column direction. Passive component interconnects 142 of passive components 140 can be coupled to substrate inward terminals 112b1 of substrate 112. In some examples, pick-and-place equipment can pick up passive components 140 and place it inside substrate 112. Subsequently, passive component interconnects 142 of passive components 140 can be bonded to substrate inward terminals 112b1 through a reflow or thermal compression bonding process.

In some examples, passive components 140 can comprise passive component interconnects 142 provided on the upper side. The lower sides of passive components 140 can be attached to the upper side of substrate 112 through an adhesive. Passive components 140 can have a lower side attached to dielectric structures of substrate 112. In some examples, the adhesive can comprise or be referred to as a polymer or a dielectric. In some examples, pick-and-place equipment can pick up passive components 140 and place it inside substrate 112. Passive components 140 can be positioned on the upper sides of dielectric structures 112a of substrate 112 and can be attached through an adhesive.

In some examples, passive components 140 can comprise or be referred to as passive components or decoupling capacitors. The overall thickness of passive components 140 can be smaller than the height of internal interconnects 152. In some examples, the overall thickness of passive components 140 can range from approximately 25 to 200 μm. In some examples, passive components 140 can be spaced apart from internal interconnects 152 with internal interconnects 152 disposed around lateral sides of passive components 140.

FIG. 2D shows a cross section view of electronic device 100 at a later stage of manufacture. In the example shown in FIG. 2D, encapsulant 162 can be provided to cover the inner side of substrate 112, passive components 140, and internal interconnects 152.

In some examples, encapsulant 162 can comprise or be referred to as a body or a molding. For example, encapsulant 162 can comprise an epoxy mold compound, a resin, a filler-reinforced polymer, a B-stage pressed film, or gel. For example, encapsulant 162 can be formed by compression molding, transfer molding, liquid body molding, vacuum lamination, paste printing, or film assist molding.

In some examples, a top portion of encapsulant 162 can be removed to expose the upper sides of internal interconnects 152 and the upper sides of passive components 140. In some examples, when passive component interconnects 142 are provided on the upper sides of passive components 140, passive component interconnects 142 can be exposed to the upper side of encapsulant 162. In some examples, when component interconnects 142 are provided on the lower sides of passive components 140, the upper sides can be exposed to the upper side of encapsulant 162.

In some examples, the top portion of encapsulant 162 can be removed by grinding. In some examples, when the top portion of encapsulant 162 is removed, the upper sides of internal interconnects 152 can be removed. The upper side of encapsulant 162 can be coplanar with the upper sides of internal interconnects 152. The thickness of encapsulant 162 and the heights of internal interconnects 152 can be similar. Encapsulant 162 can be in contact with the inner side of substrate 112, sidewalls of passive components 140, and sidewalls of internal interconnects 152. In some examples, the thickness of encapsulant 162 can range from approximately 13 to 210 μm.

FIG. 2E shows a cross section view of electronic device 100 at a later stage of manufacture. In the example shown in FIG. 2E, substrate 114 can be provided on the upper side of encapsulant 162. Substrate 114 can comprise dielectric structures 114a and conductive structures 114b. Conductive structures 114b can comprise substrate inward terminals 114b1 and substrate outward terminals 114b2.

In some examples, substrate outward terminals 114b2 can be provided on the upper side of encapsulant 162. Substrate outward terminals 114b2 can be provided to have patterns on the upper side of encapsulant 162, the upper sides of internal interconnects 152, and the upper sides of passive components 140. Substrate outward terminals 114b2 can be in contact with the upper sides of internal interconnects 152. Substrate outward terminals 114b2 can be in contact with passive component interconnects 142 of passive components 140. Substrate outward terminals 114b2 can include corresponding elements, features, materials, or manufacturing methods similar to or the same as those previously described for substrate outward terminals 112b2 of substrate 112.

Dielectric structures 114a can be provided on the upper sides of substrate outward terminals 114b2 and encapsulant 162 in some examples. After dielectric structures 114a are provided to cover substrate outward terminals 114b2 and encapsulant 162, openings exposing substrate outward terminals 114b2 can be provided. Dielectric structures 114a can include corresponding elements, features, materials, or manufacturing methods similar to or the same as those previously described for dielectric structures of substrate 112. Dielectric structures 114a can comprise one or more layers.

Some examples of conductive structures 114b can be provided to cover the upper sides of dielectric structures 114a and substrate outward terminals 114b2. Conductive structures 114b can be provided to have patterns, and the respective patterns can be electrically connected to conductive structures 114b. Conductive structures 114b can include corresponding elements, features, materials, or manufacturing methods similar to or the same as those previously described for conductive structures 112b of substrate 112. One or more layers or elements of conductive structures 114b can be interleaved with dielectric structures 114a.

In some examples, substrate outward terminals 114b2 can be parts of conductive structures 114b. Conductive structures 114b can be positioned on the upper sides of dielectric structures 114a and can comprise or be referred to as substrate inward terminals 114b1.

Completed substrate 114 can be a redistribution layer (“RDL”) substrate in some examples. Although completed substrate 114 has been shown as including two layers of dielectric structures 114a and three layers of conductive structures 114b, substrate 114 can comprise any number of layers. Substrate 114 can comprise or be referred to as a RDL, interposer, or redistribution structure. Substrate inward terminals 114b1 and substrate outward terminals 114b2 can be provided in a row or column and can be located on a lower side or upper side of substrate 114 in the depicted example. In some examples, the overall thickness of substrate 114 can range from approximately 5 to 60 μm.

FIG. 2F shows a cross section view of electronic device 100 at a later stage of manufacture. In the example shown in FIG. 2F, electronic component 120 can be provided inside substrate 114. Electronic component 120 can be in contact with or be electrically connected to substrate outward terminals 114b2 of substrate 114. In some examples of electronic component 120, the lower side can comprise or be referred to as an active side and the upper side can comprise or be referred to as an inactive side. Electronic component 120 can comprise component interconnects 122 on the lower side. Component interconnects 122 can be provided on the lower side of electronic component 120 and can be spaced apart from each other in a row or column. Component interconnects 122 can comprise or be referred to as bumps, pads, or pillars. Component interconnects 122 can be input/output terminals of electronic component 120. In some examples, component interconnects 122 can be provided on the lower side of electronic component 120 through electrolytic plating, electroless plating, sputtering, PVD, CVD, MOCVD, ALD, LPCVD, or PECVD. For example, after a photoresist pattern exposing the bond pad of electronic component 120 is provided, component interconnects 122 can be provided in contact with the exposed bond pad. In some examples, the thicknesses of component interconnects 122 can range from approximately 10 to 100 μm, and the width and pitch can range from approximately 20 to 300 μm.

In some examples, pick-and-place equipment can pick up electronic component 120 and place it inside substrate 114. Component interconnects 122 of electronic component 120 can be located on the upper sides of substrate inward terminals 114b1 of substrate 114. Subsequently, component interconnects 122 of electronic component 120 can be bonded to substrate inward terminals 114b1 through a reflow or thermal compression bonding process. In some examples, electronic component 120 can comprise or be referred to as a die, a chip, or a package. Electronic component 120 can be electrically connected to substrate 112 through conductive structures 114b of substrate 114 and internal interconnects 152. In some examples, electronic component 120 can be electrically connected to passive components 140 through substrate 114. In some examples, electronic component 120 can be electrically connected to passive components 140 through conductive structures 114b of substrate 114, internal interconnects 152, and substrate 112.

Underfill 130 can be positioned between electronic component 120 and substrate 114 in various examples. Underfill 130 can be in contact with the lower side of electronic component 120 and the inner side of substrate 114. Underfill 130 can be in contact with component interconnects 122 of electronic component 120. Underfill 130 can comprise or be referred to as a dielectric layer or a non-conductive paste. Underfill 130 can be free of inorganic fillers. In some examples, underfill 130 can comprise or be referred to as CUF, NCP, NCF, ACF, or ACP. In some examples, when underfill 130 includes molded underfill (MUF), underfill 130 can be considered part of encapsulant 164. In some examples, underfill 130 can be cured after being positioned between electronic component 120 and substrate 114. In some examples, after underfill 130 is provided to cover the inside of substrate 114, component interconnects 122 of electronic component 120 can pass through underfill 130 and be connected to substrate outward terminals 114b2. Underfill 130 can prevent electronic component 120 from being separated from substrate 114 due to physical and chemical impact.

Although electronic component 120 is shown in a face-down or flip-chip configuration with component terminals located on the lower side in the example of FIG. 2F, electronic component 120 can have a face-up or wire bonding configuration with component terminals located on the upper side. For example, in electronic component 120, the upper side can comprise or be referred to as an active side, and the lower side can comprise or be referred to as an inactive side. The inactive side of electronic component 120 can be bonded to the inside of substrate 114. In electronic component 120, component terminals can be located on the upper side having the active side. Electronic component 120 can comprise or be referred to as a face-up or wire-bonded component. Component terminals of electronic component 120 can be electrically connected to substrate inward terminals 114b1 of substrate 114 through component interconnects 122. Component interconnects 122 can comprise or be referred to as conductive wires. For example, the conductive wires are conductive wires such as gold wires, copper wires, or aluminum wires, and component terminals of electronic component 120 can be bonded to substrate inward terminals 114b1 of substrate 114 through a wire bonding device. In some examples, the overall thickness of electronic component 120 can range from approximately 50 to 780 μm, and the area can range from approximately 0.3 mm×0.3 mm to 70 mm×70 mm.

FIG. 2G shows a cross section view of electronic device 100 at a later stage of manufacture. In the example shown in FIG. 2G, internal interconnects 154 can be provided on substrate 114. Internal interconnects 154 can be in contact with or electrically connect to substrate inward terminals 114b1 of substrate 114. Internal interconnects 154 can be spaced apart from electronic component 120 with internal interconnects 154 disposed around lateral sides of electronic component 120. Internal interconnects 154 can include corresponding elements, features, materials, or manufacturing methods similar to or the same as those previously described for internal interconnects 152. The heights of internal interconnects 154 can be greater than the thickness of electronic component 120. In some examples, the thicknesses of internal interconnects 152 can range from approximately 3 to 200 μm.

FIG. 2H shows a cross section view of electronic device 100 at a later stage of manufacture. In the example shown in FIG. 2H, encapsulant 164 can be provided to cover the inside of substrate 114, electronic component 120, and internal interconnects 154. Encapsulant 164 can be in contact with the inside of substrate 114, sidewalls of internal interconnects 154, and sidewalls of electronic component 120. Encapsulant 164 can include corresponding elements, features, materials, or manufacturing methods similar to or the same as those previously described for encapsulant 162. In some examples, when the top portion of encapsulant 164 is removed, the top portions of internal interconnects 154 can also be removed. The upper side of encapsulant 164 can be coplanar with the upper sides of internal interconnects 154. The thickness of encapsulant 164 and the heights of internal interconnects 154 can be similar. In some examples, the thickness of encapsulant 164 can range from approximately 100 to 1200 μm.

FIG. 2I shows a cross section view of electronic device 100 at a later stage of manufacture. In the example shown in FIG. 2I, substrate 116 can be provided on the upper side of encapsulant 164. Substrate 116 can comprise dielectric structures 116a and conductive structures 116b. Conductive structures 116b can comprise substrate inward terminals 116b1 and antenna pattern 116b3. Conductive structures 116b can comprise or be referred to as redistribution layers (“RDLs”).

Substrate inward terminals 116b1 can be provided to the upper side of encapsulant 164, in some examples. Substrate inward terminals 116b1 can have patterns on the upper side of encapsulant 164 and the upper sides of internal interconnects 154. Substrate inward terminals 116b1 can be coupled to the upper sides of internal interconnects 154. Substrate inward terminals 116b1 can include corresponding elements, features, materials, or manufacturing methods similar to or the same as those previously described for substrate outward terminals 112b2 of substrate 112.

Some examples of dielectric structures 116a can be provided over substrate inward terminals 116b1 and the upper side of encapsulant 164. After dielectric structures 116a are provided to cover substrate inward terminals 116b1 and encapsulant 164, openings exposing substrate inward terminals 116b1 can be provided. Dielectric structures 116a can include corresponding elements, features, materials, or manufacturing methods similar to or the same as those previously described for dielectric structure 112a of substrate 112. Dielectric structures 116a can comprise one or more layers.

Antenna pattern 116b3 and conductive structures 116b can be provided to cover the upper sides of dielectric structures 116a and substrate inward terminals 116b1, in some examples. Antenna pattern 116b3 can be positioned on the upper sides of dielectric structures 116a. Antenna pattern 116b3 can be electrically connected to substrate inward terminals 116b1 through conductive structures 116b, respectively. In some examples, antenna pattern 116b3 can be a dipole antenna, a monopole antenna, a patch antenna, a loop antenna, a beam antenna, a doublet antenna, a folded antenna, a Rhombic antenna, or a half wave antenna. In some examples, antenna pattern 116b3 can comprise copper, gold, or silver. Since antenna pattern 116b3 is provided as substrate 116 (e.g., a redistribution structure), the size and position of the antenna can be tightly controlled to enable fine size adjustments.

In some examples, substrate 116 can be a redistribution layer (“RDL”) substrate. Antenna pattern 116b3 can be electrically connected to electronic component 120 through conductive structures 116b, internal interconnects 154, and conductive structures 114b of substrate 114. Although substrate 116 is shown as including two layers of dielectric structures 116a and two layers of conductive structures 116b, the number of these layers can be less or more than these. Substrate 116 can comprise or be referred to as a RDL substrate, an interposer, or an antenna substrate. Substrate inward terminals 116b1 can be provided to be spaced apart from each other in a row or column. In some examples, the overall thickness of substrate 116 can range from approximately 5 to 60 μm.

FIG. 2J shows a cross section view of electronic device 100 at a later stage of manufacture. In the example shown in FIG. 2J, external interconnects 170 can be provided outside of substrate 112.

Before external interconnects 170 are provided outside substrate 112, carrier 10 can be separated from the outside of substrate 112. In some examples, after adhesion of temporary bond layer interposed between carrier 10 and substrate 112 is released or reduced by applying heat, light, a chemical solution, or a physical external force, carrier 10 can be separated from the lower side of substrate 112. The temporary bond layer of carrier 10 can be separated from substrate 112 while remaining attached to carrier 10. Carrier 10 can be removed to expose the outside of substrate 112.

In some examples, external interconnects 170 can be coupled to substrate outward terminals 112b2 of substrate 112. In some examples, external interconnects 170 can comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 170 can be formed through a reflow process after forming a conductive material including solder on substrate outward terminals 112b2 through a ball-drop process. External interconnects 170 can comprise or be referred to as conductive balls such as solder balls, conductive pillars such as copper pillars, or conductive posts having solder caps formed on copper pillars. In some examples, external interconnects 170 can be ball-grid arrayed or land-grid-arrayed outside substrate 112. In some examples, the sizes of external interconnects 170 can range from approximately 25 to 500 μm. In some examples, external interconnects 170 can be referred to as external input/output terminals of electronic device 100.

In some examples, external interconnects 170 can be electrically connected to electronic component 120 through substrate 112, internal interconnects 152, and substrate 114. External interconnects 170 can be coupled to passive components 140 through substrate 112.

In some examples, singulation can be performed to separate substrates 112, 114, and 116 and encapsulants 162 and 164 into individual electronic devices 100. Electronic device 100 can comprise substrates 112, 114, and 116, electronic component 120, underfill 130, passive components 140, internal interconnects 152 and 154, encapsulants 162 and 164, and external interconnects 170. In electronic device 100, with electronic component 120 and passive components 140 stacked through substrate 114, and substrate 116 including a patterned antenna, a short electrical path and a miniaturized overall size can be achieved. In some examples, in electronic device 100, passive components 140 can be provided outside of substrate 112 or substrate 116.

FIG. 3 shows a cross-sectional view of an example electronic device 100′. In the example shown in FIG. 3, electronic device 100′ can comprise substrates 112, 114, and 116, electronic components 120 and 220, underfills 130 and 230, passive components 140, internal interconnects 152 and 154, encapsulants 162 and 164, and external interconnects 170.

Electronic device 100′ can be similar to electronic device 100 in some examples. For example, electronic device 100′ can be similar to electronic device 100 in terms of substrates 112, 114, and 116, electronic component 120, underfills 130 and 230, passive components 140, internal interconnects 152 and 154, encapsulants 162 and 164, and external interconnects 170. Electronic device 100′ can comprise electronic component 220 and underfill 230.

In some examples, electronic component 220 can comprise component interconnects 222. Electronic component 220 can be coupled to substrate outward terminals 112b2 of substrate 112. In some examples of electronic component 220, the lower side can comprise or be referred to as an inactive side, and the upper side can comprise or be referred to as an active side. Electronic component 220 can comprise interconnect 222 on the upper side. Component interconnects 222 can be provided to be spaced apart from each other in a row or column direction on the upper side of electronic component 220. Component interconnects 222 can include corresponding elements, features, materials, or manufacturing methods similar to or the same as those previously described for component interconnects 122 of electronic component 120.

Electronic component 220 can include corresponding elements, features, materials, or manufacturing methods similar to or the same as those previously described for electronic component 120. In some examples, electronic component 220 can be electrically coupled to antenna pattern 116b3 of substrate 116 through substrate 112, internal interconnects 152, substrate 114, and internal interconnects 154. In some examples, electronic component 220 can be electrically connected to passive components 140 or external interconnects 170 through substrate 112. In some examples, electronic component 220 can be electrically connected to passive components 140 or electronic component 120 through substrate 112, internal interconnects 152, and substrate 114.

In some examples, underfill 230 can be positioned between the outside of substrate 112 and the upper side of electronic component 220. Underfill 230 can be in contact with the upper side of electronic component 220 and the outside of substrate 112. Underfill 230 can include corresponding elements, features, materials, or manufacturing methods similar to or the same as those previously described for underfill 130. When underfill 230 includes molded underfill (MUF), electronic component 220 can be covered by the encapsulant, and underfill 230 can be considered part of the encapsulant. External interconnects 170 can be exposed through the encapsulant. In some examples of electronic device 100′, when external interconnects 170 are land-grid-arrayed, an underfill 230 can be used.

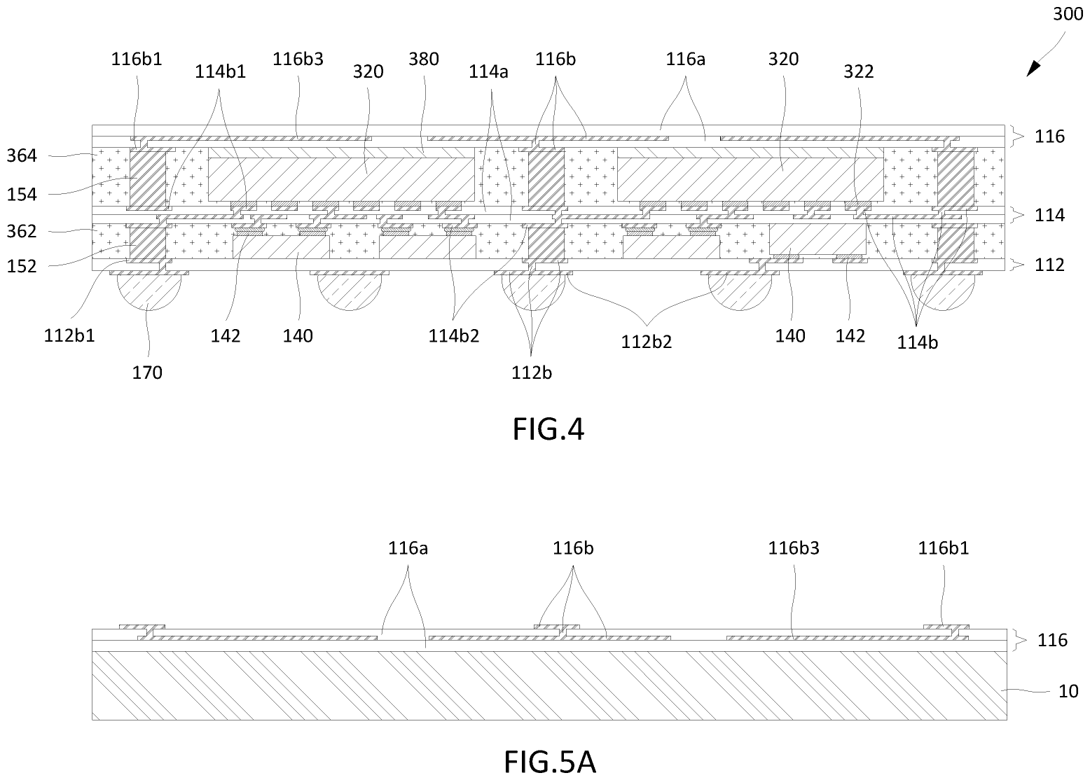

FIG. 4 shows a cross-sectional view of an example electronic device 300. In the example shown in FIG. 4, electronic device 300 can comprise substrates 112, 114, and 116, electronic component 320, passive components 140, internal interconnects 152 and 154, encapsulants 362 and 364, external interconnects 170, and die attach material 380.

Electronic device 300 can be similar to electronic device 100 in some examples. For example, electronic device 300 can be similar to electronic device 100 in terms of substrates 112, 114, and 116, passive components 140, internal interconnects 152 and 154, encapsulant 362, and external interconnects 170. Electronic device 300 can comprise electronic component 320, encapsulant 364, and die attach material 380. Electronic component 320 can comprise component interconnects 322.

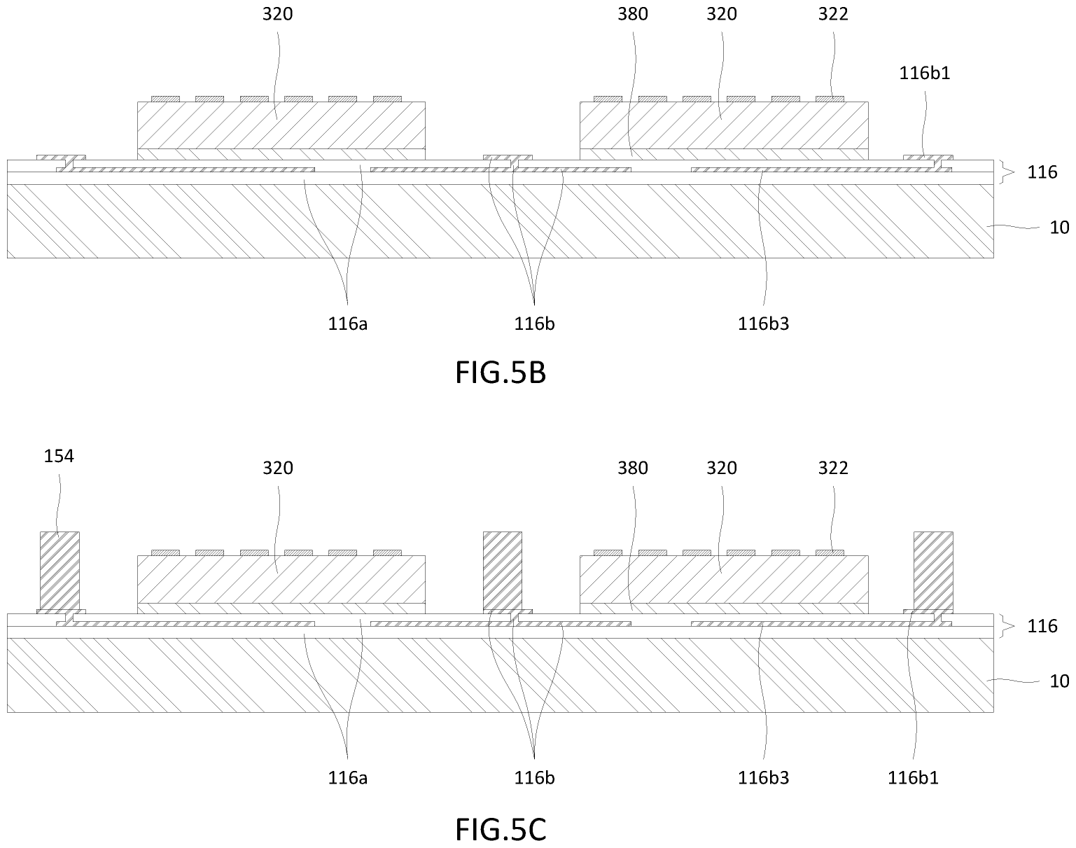

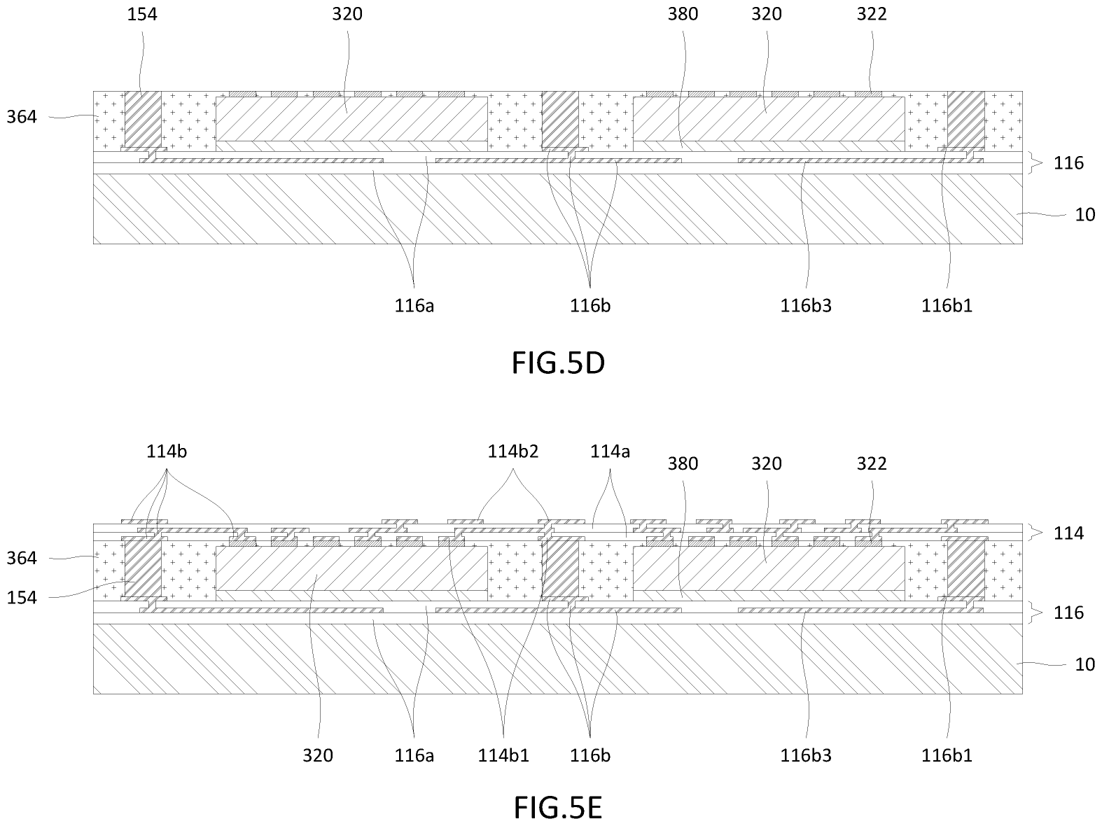

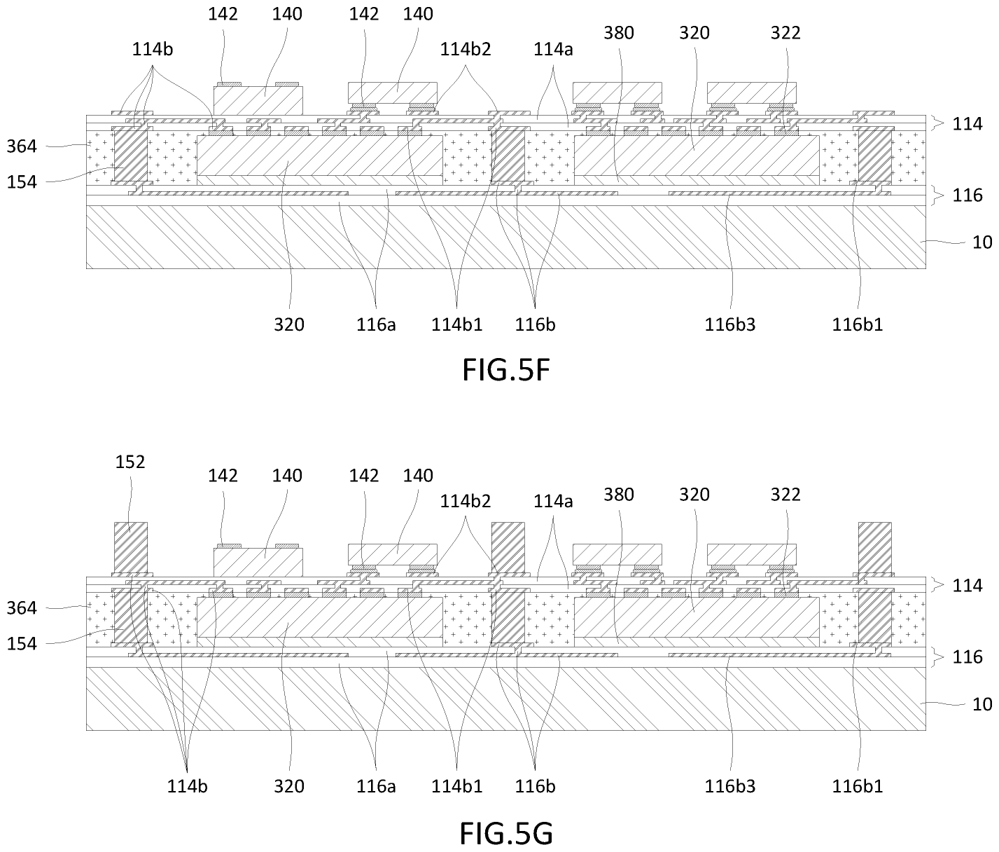

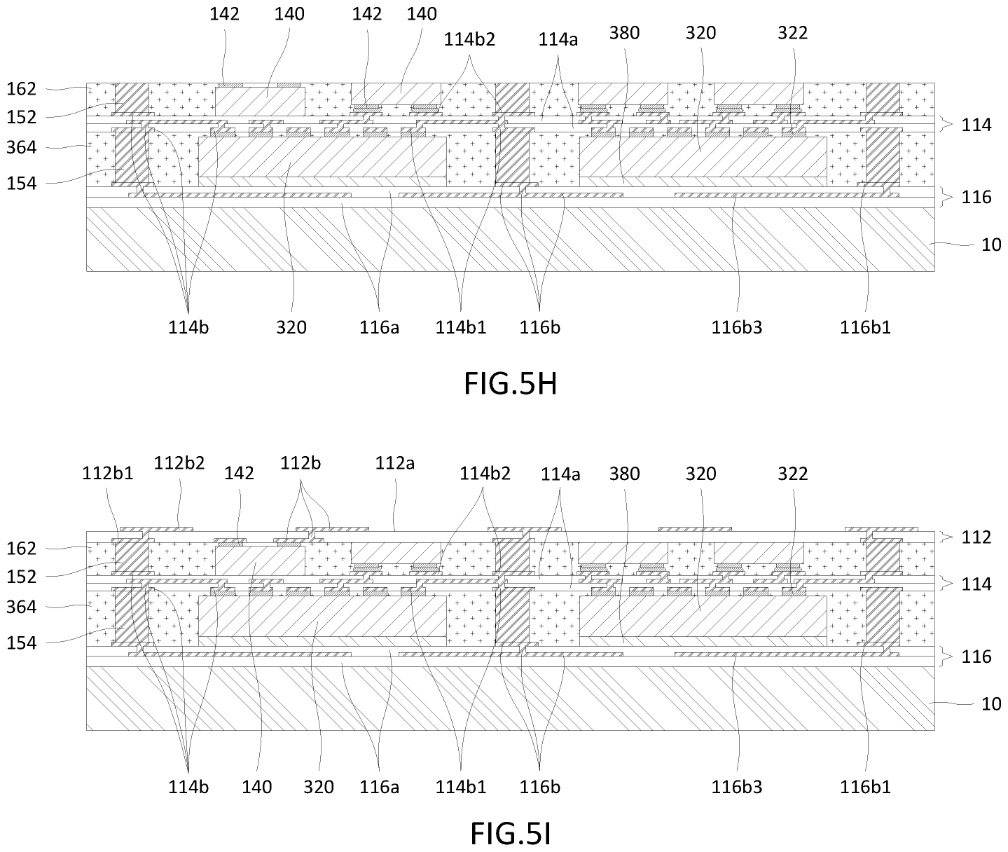

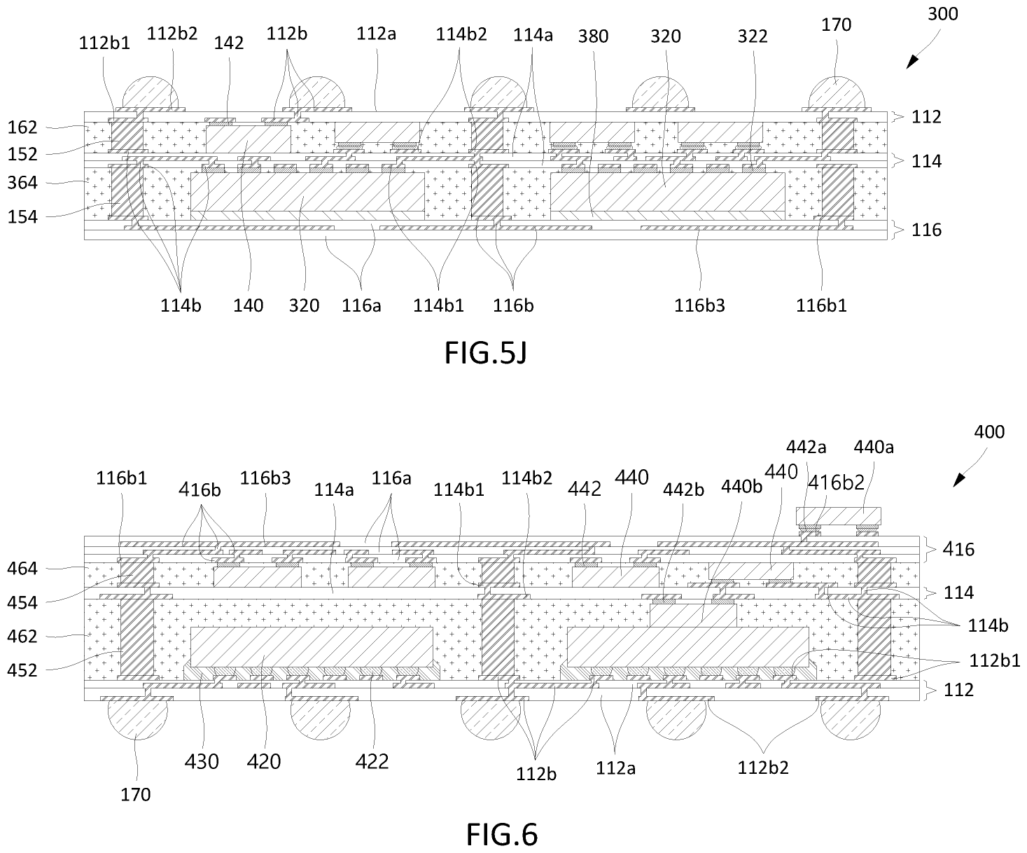

FIGS. 5A to 5J illustrate an example method for manufacturing an electronic device. FIG. 5A shows a cross section view of electronic device 300 at an early stage of manufacture. In the example shown in FIG. 5A, substrate 116 can be provided on the surface of carrier 10. Substrate 116 can comprise dielectric structures 116a and conductive structures 116b. Conductive structures 116b can comprise substrate inward terminals 116b1 and antenna pattern 116b3. In substrate 116, dielectric structures 116a can be provided, conductive structures 116b comprising antenna pattern 116b3 can be provided, dielectric structures 116a can be provided, and conductive structures 116b comprising substrate inward terminals 116b1 can then be provided. Substrate inward terminals 116b1 can be positioned on the upper sides of dielectric structures 116a. Although substrate 116 is shown as including two layers of dielectric structures 116a and two layers of conductive structures 116b, substrate 116 can comprise any number of layers. Carrier 10 and substrate 116 can include corresponding elements, features, materials, or manufacturing methods similar to or the same as those previously described for carrier 10 and substrate 116.

FIG. 5B shows a cross section view of electronic device 300 at a later stage of manufacture. In the example shown in FIG. 5B, electronic component 320 can be provided inside substrate 116. In some examples, electronic component 320 can comprise electronic component interconnects 322 provided on the upper side. For example, in electronic component 120, the upper side can comprise or be referred to as an active side, and the lower side can comprise or be referred to as an inactive side. The inactive side of electronic component 120 can be bonded to the inside of substrate 116. Electronic component 320 can be attached to the inside of the dielectric structure of substrate 116 by die attach material 380. In some examples, die attach material 380 can comprise an adhesive layer or an adhesive film. In some examples, die attach material 380 can be provided by performing, on the inner side of substrate 116, a coating process such as spin coating, doctor blade coating, casting, painting, spray coating, slot die coating, curtain coating, slide coating, or knife over edge coating, a printing process such as screen printing, pad printing, gravure printing, flexography printing, or offset printing, an inkjet printing process, an intermediate technology between coating and printing, or by direct attachment of an adhesive film or an adhesive tape.

In some examples, pick-and-place equipment can pick up electronic component 320 and place on the upper side of die attach material 380 inside dielectric structures 116a of substrate 116, to then be attached to the upper side of substrate 116 through die attach material 380. Electronic component 320 can include corresponding elements, features, materials, or manufacturing methods similar to or the same as those previously described for electronic component 120 of electronic device 100. In some examples, the thickness of electronic component 320 can range from approximately 25 to 780 μm.

FIG. 5C shows a cross section view of electronic device 300 at a later stage of manufacture, though the steps of FIGS. 5B and 5C can be performed in any order. In the example shown in FIG. 5C, internal interconnects 154 can be provided over substrate 116. Internal interconnects 154 can be coupled to substrate inward terminals 116b1 of substrate 116. The heights of internal interconnects 154 can be greater than the overall thickness of electronic component 320. Internal interconnects 154 can include corresponding elements, features, materials, or manufacturing methods similar to or the same as those previously described for internal interconnects 154 of electronic device 100.

FIG. 5D shows a cross section view of electronic device 300 at a later stage of manufacture. In the example shown in FIG. 5D, encapsulant 364 can be provided to cover the inside of substrate 116, internal interconnects 154, and electronic component 320. Encapsulant 364 can be in contact with the inside of substrate 116, sidewalls of internal interconnects 154, sidewalls of electronic component 320, and sidewalls of die attach material 380. In some examples, when the top portion of encapsulant 364 is removed, the top portions of internal interconnects 154 can also be removed.

Component interconnects 322 of electronic component 320 can be exposed to the upper side of encapsulant 364, in some examples. The upper side of encapsulant 364 can be coplanar with the upper side of internal interconnects 154 and the upper sides of component interconnects 322 of electronic component 320. The thickness of encapsulant 364 and the heights of internal interconnects 154 can be similar. Encapsulant 364 can include corresponding elements, features, materials, or manufacturing methods similar to or the same as those previously described for encapsulant 164 of electronic device 100.

FIG. 5E shows a cross section view of electronic device 300 at a later stage of manufacture. In the example shown in FIG. 5E, substrate 114 can be provided to cover the upper side of encapsulant 364, the upper sides of interconnects 154, and the upper sides of component interconnects 322 of electronic component 320. Substrate 114 can comprise dielectric structures 114a and conductive structures 114b. Conductive structures 114b can comprise substrate inward terminals 114b1 and substrate outward terminals 114b2. In substrate 114, substrate inward terminals 114b1 can be provided, dielectric structures 114a and conductive structures 114b can be provided, dielectric structures 114a can be provided, and conductive structures 114b comprising substrate outward terminals 114b2 can then be provided.

In some examples, substrate inward terminals 114b1 can be coupled to the upper side of interconnect 154 or the upper sides of component interconnects 322 of electronic component 320. Substrate outward terminals 114b2 can be positioned on the upper sides of dielectric structures 114a. Although substrate 114 is shown as including two layers of dielectric structures 114a and three layers of conductive structures 114b, the number of layers can be less than or greater than the number depicted in the examples. In some examples, electronic component 320 can be electrically connected to antenna pattern 116b3 of substrate 116 through conductive structures 114b of substrate 114 and interconnects 154. Substrate 114 can include corresponding elements, features, materials, or manufacturing methods similar to or the same as those previously described for substrate 114 of electronic device 100.

FIG. 5F shows a cross section view of electronic device 300 at a later stage of manufacture. In the example shown in FIG. 5F, passive components 140 can be provided inside substrate 114. In some examples, passive components 140 can comprise passive component interconnects 142 provided on the upper side or lower side. In some examples, component interconnects 142 provided to the lower side of passive components 140 can be coupled to substrate inward terminals 114b1. In some examples, passive components 140 can comprise component interconnects 142 on the upper side and adhere to substrate 114 on the lower side. Passive components 140 can comprise one or more than two passive components. Passive components 140 can include corresponding elements, features, materials, or manufacturing methods similar to or the same as those previously described for passive components 140 of electronic device 100. In some examples, passive components 140 can be electrically connected to electronic component 320 through substrate 114.

FIG. 5G shows a cross section view of electronic device 300 at a later stage of manufacture. In the example shown in FIG. 5G, internal interconnects 152 can be provided inside substrate 114. In some examples, internal interconnects 152 can be coupled to substrate inward terminals 114b1 of substrate 114. The heights of internal interconnects 152 can be greater than the overall thickness of passive components 140. Internal interconnects 152 can include corresponding elements, features, materials, or manufacturing methods similar to or the same as those previously described for internal interconnects 152 of electronic device 100.

FIG. 5H shows a cross section view of electronic device 300 at a later stage of manufacture. In the example shown in FIG. 5H, encapsulant 162 can be provided to cover the outside of substrate 114, internal interconnects 152, and passive components 140. Encapsulant 162 can be in contact with the outside of substrate 114, sidewalls of internal interconnects 152, and sidewalls of passive components 140. In some examples, when the top portion of encapsulant 162 is removed, the top portions of internal interconnects 152 can also be removed.

In some examples, passive component interconnects 142 positioned on the upper sides of passive components 140 can be exposed of encapsulant 162. The upper side of encapsulant 162 can be coplanar with the upper sides of internal interconnects 152 and the upper side of electronic component 320. Encapsulant 162 can include corresponding elements, features, materials, or manufacturing methods similar to or the same as those previously described for encapsulant 164 of electronic device 100.

FIG. 5I shows a cross section view of electronic device 300 at a later stage of manufacture. In the example shown in FIG. 5I, substrate 112 can be provided to the upper side of encapsulant 162 and the upper sides of internal interconnects 152. Substrate 112 can comprise dielectric structure 112a and conductive structure 112b. Conductive structures 112b can comprise substrate inward terminals 112b1 and substrate outward terminals 112b2. In substrate 112, substrate inward terminals 112b1 can be provided, dielectric structures 112a can be provided, and conductive structures 112b comprising substrate outward terminals 112b2 can then be provided. Substrate inward terminals 112b1 can be coupled to the upper side of interconnect 152 and the upper sides of passive component interconnects 142 of passive components 140. Substrate outward terminals 112b2 can be positioned on the upper sides of dielectric structures 112a. Although substrate 112 is shown as including one layer of dielectric structure 112a and two layers of conductive structures 112b, the number of layers can be less or more than these. Substrate 112 can include corresponding elements, features, materials, or manufacturing methods similar to or the same as those previously described for substrate 112 of electronic device 100.

FIG. 5J shows a cross section view of electronic device 300 at a later stage of manufacture. In the example shown in FIG. 5J, external interconnects 170 can be provided to substrate outward terminals 112b2 of substrate 112. Before or after external interconnects 170 are provided, carrier 10 can be removed from the outside of substrate 116. External interconnects 170 can include corresponding elements, features, materials, or manufacturing methods similar to or the same as those previously described for external interconnects 170 of electronic device 100. After external interconnects 170 are provided, electronic device 300 can be flipped so external interconnects 170 are positioned at the bottommost side and substrate 116 is positioned at the topmost side.

In some examples, electronic device 300 can comprise substrates 112, 114, and 116, electronic component 320, passive components 140, internal interconnects 152 and 154, encapsulants 362 and 364, external interconnects 170, and die attach material 380. In some examples of electronic device 300, electronic component 220 can be provided outside substrate 112. Electronic component 220 can be similar to electronic component 220 of electronic device 100′ shown in FIG. 3.

FIG. 6 shows a cross-sectional view of an example electronic device 400. In the example shown in FIG. 6, electronic device 400 can comprise substrates 112, 114, and 416, electronic component 420, underfill 430, passive components 440, 440a, and 440b, internal interconnects 452 and 454, encapsulants 462 and 464, and external interconnects 170.

Some examples of electronic device 400 can be similar to electronic device 100. For example, electronic device 400 can be similar to electronic device 100 in terms of substrates 112 and 114 and external interconnects 170. Electronic device 400 can comprise substrate 416, electronic component 420, underfill 430, passive components 440, 440a, and 440b, internal interconnects 452 and 454, and encapsulants 462 and 464.

In some examples, substrate 416 can be similar to substrate 116 of electronic device 100. Substrate 416 can comprise substrate outward terminals, which can comprise a portion of conductive structures 416b exposed from dielectric structures 116a. Substrate outward terminals 416b2 can be positioned outside substrate 416 on an outer surface of electronic device 400.

Some examples of electronic component 420 can be coupled to substrate inward terminals 112b1 of substrate 112. Underfill 430 can be interposed between the inside of substrate 112 and the lower side of electronic component 420. Electronic component 420 and underfill 430 can include corresponding elements, features, materials, or manufacturing methods similar to or the same as those previously described for electronic component 120 and underfill 130 of electronic device 100, respectively.

In some examples, encapsulant 462 can be in contact with the upper side of electronic component 420 and sidewalls of internal interconnects 452. Encapsulant 462 can be interposed between the inside of substrate 112 and the outside of substrate 114. Encapsulant 462 can include corresponding elements, features, materials, or manufacturing methods similar to or the same as those previously described for encapsulant 164 of electronic device 100. Internal interconnects 452 can electrically connect substrate inward terminals 112b1 of substrate 112 and substrate outward terminals 114b2 of substrate 114 to each other. Internal interconnects 452 are similar to encapsulant 462 covering electronic component 420 in terms of height. Internal interconnects 452 can include corresponding elements, features, materials, or manufacturing methods similar to or the same as those previously described for interconnects 154 of electronic device 100.

In some examples, passive components 440 can be coupled to substrate inward terminals 114b1 of substrate 114. Passive components 440 can be coupled to substrate inward terminals 116b1 of substrate 116. Passive components 440 can include corresponding elements, features, materials, or manufacturing methods similar to or the same as those previously described for passive components 140 of electronic device 100. In some examples, passive components 440 can be coupled to substrate outward terminals 112b2 of substrate 112.

In some examples, encapsulant 464 can be in contact with sidewalls of passive components 440 and sidewalls of internal interconnects 454. Encapsulant 464 can be interposed between the inside of substrate 114 and the inside of substrate 116. Encapsulant 464 can include corresponding elements, features, materials, or manufacturing methods similar to or the same as those previously described for encapsulant 162 of electronic device 100.

In some examples, internal interconnects 452 can electrically connect substrate inward terminals 114b1 of substrate 114 and substrate inward terminals 116b1 of substrate 116 to each other. Internal interconnects 454 can be similar to encapsulant 464 covering passive components 440 in terms of height. Internal interconnects 454 can include corresponding elements, features, materials, or manufacturing method similar to or the same as those previously described for interconnects 152 of electronic device 100.

Passive component 440a can be coupled to substrate outward terminals 416b2 of substrate 116, in various examples. Passive component 440 can be located on an outer side of substrate 116. Passive component 440a can comprise passive component interconnects 442a spaced apart from each other in a row or column direction at a lower side. In passive component 440a, passive component interconnects 442a can be coupled to substrate outward terminals 416b2 of substrate 116. Passive component 440a can be electrically connected to electronic component 420 through substrate 416, interconnects 454, substrate 114, interconnects 452, and substrate 112. Passive component 440a can include corresponding elements, features, materials, or manufacturing methods similar to or the same as those previously described for passive components 140 of electronic device 100.

Some examples of passive component 440b can be coupled to substrate outward terminals 114b2 of substrate 114. The lower side of passive component 440b can be in contact with the upper side of electronic component 420. Passive component 440b can comprise passive component interconnects 442b provided on the upper side and can be spaced apart in a row or column. In passive component 440b, passive component interconnects 442b can be coupled to substrate outward terminals 114b2 of substrate 114. Passive component 440b can be electrically connected to electronic component 420 through substrate 114, interconnects 452, and substrate 112.

In some examples, electronic component 420 can be electrically connected to antenna pattern 116b3 through conductive structures 112b of substrate 112, internal interconnects 452, conductive structures 114b of substrate 114, internal interconnects 454, and conductive structures 416b of substrate 416. In some examples, passive components 440 can be electrically connected to electronic component 420 through conductive structures 114b of substrate 114, internal interconnects 452, and conductive structures 112b of substrate 112. In some examples, passive components 440 can be electrically connected to electronic component 420 through conductive structures 416b of substrate 416, internal interconnects 454, conductive structures 114b of substrate 114, interconnects 452, and structures 112b of substrate 112. External interconnects 170 can be electrically connected to electronic component 420 through substrate 112.

Example devices and methods described above can include a patterned antenna formed in a substrate and vertically stacked passive components and electronic components. The patterned antenna tends to result in improved control over antenna dimensions. Stacked electronic components, passive components, and patterned antenna tend to reduce package size and can result in short electrical paths between the antenna, electronic components, and passive components.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a first redistribution structure;
a first electronic component on a first side of the first redistribution structure;
a first passive component on a second side of the first redistribution structure, wherein the first redistribution structure is between the first passive component and the first electronic component;
a first internal interconnect adjacent a lateral side of the first redistribution structure and coupled to the first redistribution structure;
a second internal interconnect adjacent a lateral side of the first passive component and coupled to the first redistribution structure;
an antenna substrate over a first side of the first electronic component; and
a second redistribution structure over a second side of the first electronic component.

2. The electronic device of claim 1, further comprising a second passive component disposed between the first redistribution structure and the first electronic component.

3. The electronic device of claim 1, further comprising a second passive component adjacent the first passive component, wherein the first redistribution structure is between the second passive component and the first electronic component.

4. The electronic device of claim 1, further comprising a second passive component coupled to an outer side of the antenna substrate, wherein the antenna substrate is between the second passive component and the first passive component.

5. The electronic device of claim 1, wherein the first passive component is between the first redistribution structure and the second redistribution structure.

6. The electronic device of claim 1, wherein the first electronic component is between the first redistribution structure and the second redistribution structure.

7. The electronic device of claim 1, further comprising a die attach material coupling the first electronic component to the antenna substrate.

8. The electronic device of claim 1, further comprising an active side of the first electronic component coupled to the second redistribution structure.

9. The electronic device of claim 1, further comprising an active side of the first electronic component coupled to the first redistribution structure.

10. The electronic device of claim 1, further comprising a second electronic component with a lateral side of the second electronic component facing towards the first internal interconnect, wherein the first internal interconnect is between the first electronic component and the second electronic component.

11. The electronic device of claim 10, further comprising a first encapsulant disposed around the first internal interconnect, the first electronic component, and the second electronic component.

12. The electronic device of claim 11, further comprising a second encapsulant disposed around the second internal interconnect and the first passive component, wherein the first redistribution structure is between the first encapsulant and the second encapsulant.

13. The electronic device of claim 1, further comprising a second electronic component coupled to an outer side of the second redistribution structure, wherein the second redistribution structure is between the second electronic component and the first electronic component.

14. A method of making an electronic device, comprising:
providing a first substrate;
providing a first internal interconnect over the first substrate;
providing a first passive component over the first substrate and adjacent a lateral side of the first internal interconnect;
providing a second substrate over the first passive component and the first internal interconnect, wherein the second substrate comprises a redistribution structure;
providing an electronic component over the second substrate;
providing a second internal interconnect adjacent a lateral side of the electronic component; and
providing a third substrate over the electronic component and the second internal interconnect, wherein the third substrate comprises an antenna.

15. The method of claim 14, further comprising providing a second passive component over the second substrate and adjacent the electronic component.

16. The method of claim 14, further comprising providing a first encapsulant over the first substrate and around the first passive component and the first internal interconnect.

17. The method of claim 16, further comprising providing a second encapsulant over the second substrate and around the electronic component and the second internal interconnect.

18. The method of claim 14, wherein providing the third substrate further comprises patterning a conductive layer to form the antenna.

19. The method of claim 14, further comprising providing a second passive component over the first substrate and adjacent the first passive component.

20. The method of claim 14, further comprising providing a second passive component over an outer side of the third substrate.
